(19) United States
(12) Patent Application Publication
(10) Pub. No.: US 2014/0291818 A1
(43) Pub. Date: Oct. 2, 2014

(54) Integrated Circuit Device Facilitating Package on Package Connections

(71) Applicant: BROADCOM CORPORATION, Irvine, CA (US)

(72) Inventors: Sam Ziqun ZHAO, Irvine, CA (US); Rezaur Rahman Khan, Irvine, CA (US)

(73) Assignee: Broadcom Corporation, Irvine, CA (US)

(21) Appl. No.: 13/850,827

(22) Filed: Mar. 26, 2013

(51) Int. Cl. H01L 23/552; H01L 21/56

(52) U.S. Cl. CPC H01L 23/552; H01L 21/56
USPC 257/659; 438/127

(57) ABSTRACT

In embodiments described herein, an integrated circuit (IC) package is provided. The IC package can include a substrate having opposing first and second surfaces, an IC die coupled to the first surface of the substrate, a first plurality of conductive elements coupled to conductive regions on the first surface of the substrate, an interposer having opposing first and second surfaces, and a second plurality of conductive elements coupled to conductive regions on the first surface of the interposer. The second surface of the substrate is configured be coupled to at least one device. Each of the first plurality of conductive elements is electrically coupled to a respective one of the second plurality of conductive elements. The interposer is configured to be attached to a printed circuit board (PCB).

### BACKGROUND

1. Field

Embodiments described herein generally relate to integrated circuit (IC) device packaging technology.

2. Background Art

Conventional array-type packages have the drawbacks of (1) poor thermal performance, (2) no EMI protections, (3) thick top mold and overall package profile height, (4) small ratio of die-to-package size since the mold cap must be clamped to the package substrate for molding, and (5) large package body size. Both the resin substrate and the plastic molding compound materials have low thermal conductivity values (around 0.19˜0.3 W/m·° C. for BT or FR4 type substrate and 0.2˜0.9 W/m·° C. for the molding compound). Since the die is surrounded entirely by materials with poor heat conduction properties, the heat generated on the IC die is trapped within the PBGA package. The temperature of the IC die has to rise to very high values above the environment temperature in order to release the trapped heat to the environment.

Both the resin substrate and the plastic molding compound materials are transparent to electromagnetic radiation. Consequently, electromagnetic radiation generated from the IC die will escape from the package and enter the electronic system and interfere with other electronic components. The IC die is also unprotected from electromagnetic radiation emitted from other components inside as well as outside the electronic system.

In conventional stacked packages, the package-to-package interconnection is facilitated by mounting a top package to the substrate of the bottom package. The bottom package can have exposed land pads on the substrate top surface Which provide contact with the solder balls on the top package. The exposed solder ball land pads are located along the periphery of the substrate top and surround the package molding compound. The top package can be attached to the bottom package using conventional reflow surface mount processes. Because the solder ball land pads on the bottom package substrate top must be exposed for stacking the top package, the IC die of the bottom package must be encapsulated with a mold cavity (mold cap) to define the extent of the mold and prevent the mold compound from covering or contaminating the ball pads. Consequently, the die size in the bottom package cannot be too large in order for both the die and bond wires to fit into the mold.

### BRIEF DESCRIPTION OF THE DRAWINGS/FIGURES

The accompanying drawings, which are incorporated herein and form a part of the specification, illustrate the disclosed subject matter and, together with the description, further serve to explain the principles of the contemplated embodiments and to enable a person skilled in the pertinent art to make and use the contemplated embodiments.

FIGS. 1-4 show cross-sectional views of IC devices, according to embodiments.

FIGS. 5-8 show cross-sectional views of substrates, according to embodiments.

FIG. 9 shows a cross-sectional, exploded view of an IC device, according to an embodiment.

FIGS. 10-13 show cross-sectional views of IC devices, according to embodiments.

FIG. 14 is flowchart of a method of manufacturing an IC device, according to an embodiment.

FIGS. 15-20 show cross-sectional views of exemplary steps in manufacturing an IC device, according to embodiments.

The disclosed subject matter will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION

The following Detailed Description refers to accompanying drawings to illustrate exemplary embodiments consistent with the disclosure. References in the Detailed Description to “one exemplary embodiment,” “an exemplary embodiment,” “an example exemplary embodiment,” etc., indicate that the exemplary embodiment described can include a particular feature, structure, or characteristic, but every exemplary embodiment can not necessarily include the particular feature, structure, or characteristic. Moreover, such phrases are not necessarily referring to the same exemplary embodiment. Further, when a particular feature, structure, or characteristic is described in connection with an exemplary embodiment, it is within the knowledge of those skilled in the relevant art(s) to affect such feature, structure, or characteristic in connection with other exemplary embodiments whether or not explicitly described.

The exemplary embodiments described herein are provided for illustrative purposes, and are not limiting. Other exemplary embodiments are possible, and modifications can be made to the exemplary embodiments within the spirit and scope of the disclosure. Therefore, the Detailed Description is not meant to limit the disclosure. Rather, the scope of the disclosure is defined only in accordance with the following claims and their equivalents.

The following Detailed Description of the exemplary embodiments will so fully reveal the general nature of the disclosure that others can, by applying knowledge of those skilled in relevant art(s), readily modify and/or adapt for various applications such exemplary embodiments, without undue experimentation, without departing from the spirit and scope of the disclosure. Therefore, such adaptations and modifications are intended to be within the meaning and plurality of equivalents of the exemplary embodiments based upon the teaching and guidance presented herein. It is to be understood that the phraseology or terminology herein is for the purpose of description and not of limitation, such that the terminology or phraseology of the present specification is to be interpreted by those skilled in relevant art(s) in light of the teachings herein.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein may be spatially arranged in any orientation or manner.

Embodiments disclosed herein include an integrated circuit (IC) package. The IC package can include a substrate, one or more IC dies, an interposer, and first and second pluralities of conductive elements. The substrate can have opposing first and second surfaces. For example, the first surface can be the bottom surface of the substrate and the second surface can be top surface of the substrate. The first IC die can be coupled to the first surface of the substrate. The first plurality of conductive elements can also be coupled to the first surface of the substrate. The interposer can have opposing, the first and second surfaces. For example, the first surface can be the top surface of the interposer and the second surface can be the bottom surface of the interposer. The second plurality of conductive elements can be coupled to the first surface of the interposer. Respective ones of the first and second pluralities of conductive elements can be electrically coupled. For example, the first and second pluralities of conductive elements can be joined using a reflow process, in an embodiment, the first IC die can be electrically coupled to the interposer through the first and second pluralities of conductive elements.

One or more devices can be coupled to the second surface of the substrate. For example, the devices can include one or more of a lead frame package, a ball grid array (BGA) package, passive components (e.g., a balun, a capacitor, or an inductor), or an antenna. For example, an IC package including a second IC die can be coupled to the second surface of the substrate. The substrate can electrically interconnect the first and second IC dies to facilitate coma between them. For example, the first IC die can include a processor and the second IC die can include a memory. The processor included in the first IC die can be configured to store data in the memory included in the second IC die.

Moreover, the package can also include an encapsulation material that encapsulates the first IC die and at least a portion of the first plurality of conductive elements. A gap can be present between the outer surface of the encapsulation material and the first surface of the interposer.

The first and second pluralities of conductive elements can include a variety of different types of conductive elements. For example, solder balls, copper posts, and/or copper posts having solder caps can be included in the first and second pluralities of conductive elements.

Furthermore, the interposer, the substrate and specific ones of the first and second pluralities of conductive elements can together form a Faraday cage. The Faraday cage can prevent electromagnetic interference of the first IC the and can prevent radiation emanating from the first IC die from exiting the IC package. For example, the substrate and the interposer can each include a patterned metal layer that can be electrically coupled through the first and second pluralities of conductive elements. A loop can thus be formed around the first IC die. This loop can then be coupled to a ground potential to form a Faraday cage.

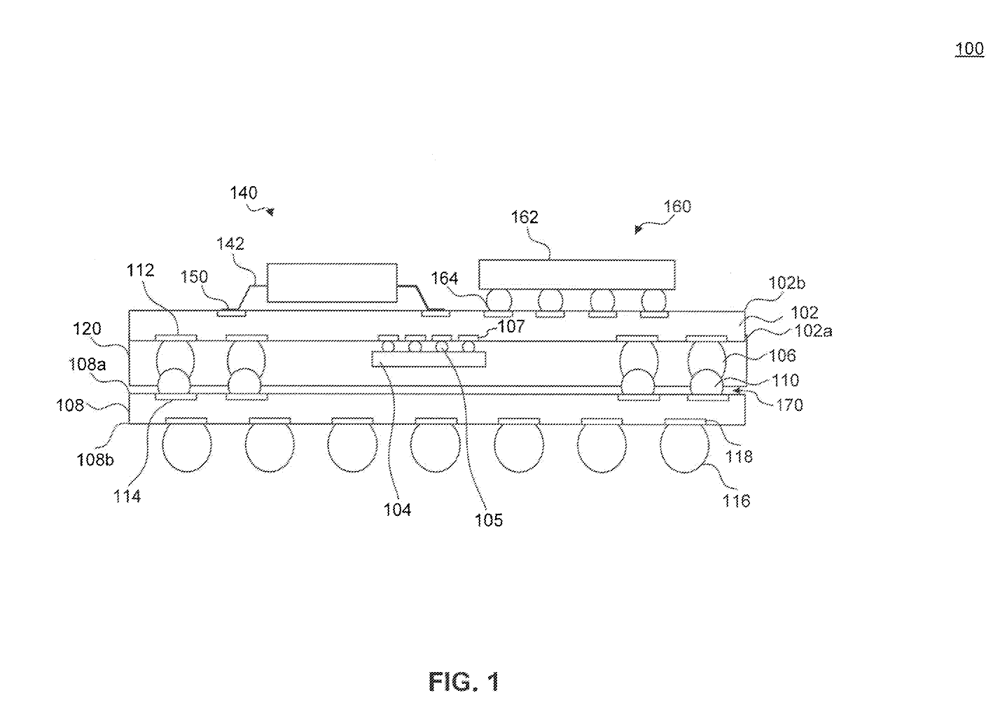

FIG. 1 shows a cross-sectional diagram of an integrated circuit (IC) package 100, according to an embodiment. IC package 100 includes a substrate 102, an IC die 104, an interposer 108, packages 140 and 160, an encapsulation material 120, and first, second, and third pluralities of conductive elements 106, 110, and 116.

As shown in FIG. 1, substrate 102 has a first (e.g., bottom) surface 102a and a second (e.g., top) surface 102b and interposer 108 has a first (e.g., top) surface 108a and a second (e.g., bottom) surface 108b. Substrate 102 and interposer 108 can include one or more dielectric layers interdigitized, e.g., sandwiched, between one or more metal layers (not shown in FIG. 1). The dielectric material can be one of a variety of different types of dielectric materials known to those skilled in the art, e.g., FR-4. In an embodiment, one or more of the metal layers can be patterned. For example, one or more of the metal layers can be patterned to include trace(s). The metal layers can include one or more variety of different types of metals, e.g., copper or aluminum. Moreover, substrate 102 and/or interposer 108 can include via(s) that electrically couple different metal layers. Substrate 102 and interposer 108 may be formed out of the same materials (e.g., the same dielectric material and/or metal) or may be formed out of afferent materials and can include different numbers of metal layers.

Conductive regions 112 and 150 are formed on first and second surfaces 102a and 102b of substrate 102, respectively. Conductive regions 112 and/or 150 can be formed by patterning a metal layer. Conductive regions 112 can be configured to be coupled to respective ones of first plurality of conductive elements 106. Conductive regions 150 can be configured to be coupled to conductive elements of packages 160 and 140. In an embodiment, conductive regions 112 and/or conductive regions 150 can include bond pads.

IC die 104 is coupled to first surface 102a of substrate 102 in a flip chip configuration. For example, as shown in FIG. 1, IC die 104 is coupled to first surface 102a of substrate 102 through solder bumps 105, which are coupled to respective conductive regions 107 of substrate 102. In an embodiment, IC die 104 can be formed out of a variety of different materials used to form IC dies. e.g., Silicon. Solder bumps 105 can be configured to electrically couple conductive regions on IC die 104 to respective conductive regions on substrate 102.

First plurality of conductive elements 106 are coupled to respective ones of conductive regions 112. In the embodiment of FIG. 1, first plurality of conductive elements 106 are implemented as solder balls. In alternate embodiments, however, first plurality of conductive elements 106 can be implemented as other types of elements, e.g., bumps, posts, pads, pins, or pillars. The solder balls of first plurality of conductive elements 106 shown in FIG. 1 can have a diameter in the range of approximately 0.30 mm-0.40 mm.

Conductive regions 114 and 118 are formed on first and second surfaces 108a and 108b of interposer 108. Conductive regions 114 can be configured to be coupled to respective ones of second plurality of conductive elements 110. Further, conductive regions 118 can be configured to be coupled to respective ones of third plurality of conductive elements 116. In an embodiment, conductive regions 114 and/or conductive regions 118 can include bond pads.

In the embodiment of FIG. 1, second plurality of conductive elements 110 is shown as including solder balls. In alternative embodiments, however, other types of conductive elements can be used, e.g., bumps, posts, pads, pins, or pillars. In an exemplary embodiment, the solder balls that make up second plurality of conductive elements 110 in the embodiment of FIG. 1 can be smaller than the solder balls that make up first plurality of conductive elements 106. For example, solder balls that make up second plurality of conductive elements 110 in FIG. 1 can have a diameter in the range of approximately 0.20 mm-0.30 mm.

Third plurality of conductive elements 116 can facilitate communication between IC package 100 and a printed circuit board (PCB) (not shown). For example, third plurality of conductive elements 116 can be configured to contact conductive regions on the PCB. These conductive regions can be coupled to elements, e.g., traces, that provide electrical coupling to other devices coupled to the PCB. In the embodiment of FIG. 1, third plurality of conductive elements 116 is shown as including solder balls. In alternative embodiments, however, other types of conductive elements can be used, e.g., posts, pads, pins, or pillars. The solder balls that make up third plurality of conductive elements 116 in the embodiment of FIG. 1 can have a diameter in the range of approximately 0.2 mm-0.4 mm.

Packages 140 and 160 are coupled to conductive regions 150 of substrate 102. Package 140 is a lead frame package that includes an IC die (not shown) and leads 142. Package 160 is a fan out includes an IC die 162 coupled to second surface 102b of substrate 102 through solder balls 164. In an embodiment, substrate 102 can electrically couple IC die 104 to package 140 and/or package 160. Moreover, substrate 102 can also electrically couple packages 140 and 160. Although the embodiment of FIG. 1 shows packages 140 and 160 being a lead frame and fan out packages, respectively, in alternate other types of IC packages having IC dies can be used (e.g., ball grid array (BGA) packages, pin arid array (PGA) packages, land grid array (LGA) packages, fan-out packages, or no-lead packages.)

For example, IC die 104 can include a processor and IC die 162 can include a memory. In such an embodiment, IC die 104 can be configured to store data in the memory of IC die 162. Because the signal path between IC die 104 and IC die 162 is relatively short, e.g., as opposed to different devices on a PCB, communications between IC dies 104 and 162 can be enhanced. These enhanced communications may, for example, enable high speed data exchanges between IC dies 104 and 162. Moreover, the relatively short distance also reduces the likelihood that electromagnetic interference will corrupt data exchanges between IC dies 104 and 162.

In a further embodiment, all or substantially all of the devices (e.g., memories, transceivers, antennas, processors, etc.) that constitute an electronics system (e.g., a cellular phone) can be mounted on first surface 102a and/or second surface 102b of substrate 102. In such an embodiment, most or all communications between devices of the system benefit from the shortened signal paths provided by substrate 102. Communications with devices mounted to a PCB can be provided through interposer 108.

Substrate 102 can also be configured to couple IC die 104 to first plurality of conductive elements 106. Through first plurality of conductive elements 106, IC die 104 can be coupled to second plurality of conductive elements 110. Moreover, interposer 108 can be configured to electrically couple second and third pluralities of conductive elements 110 and 116. Thus, IC die 104 can be electrically coupled to third plurality of conductive elements 116, e.g., to allow for communications to a PCB.

Encapsulation material 120 encapsulates IC die 104, solder bumps 105, and a least a portion of first plurality of conductive elements 106. As shown in FIG. 1, a gap 170 exists between the outer surface of encapsulation material 120 and first surface 108a of interposer 108. As will be described below, however, in alternate embodiments no gap exists between the outer surface of encapsulation material 120 and first surface 108a of interposer 108.

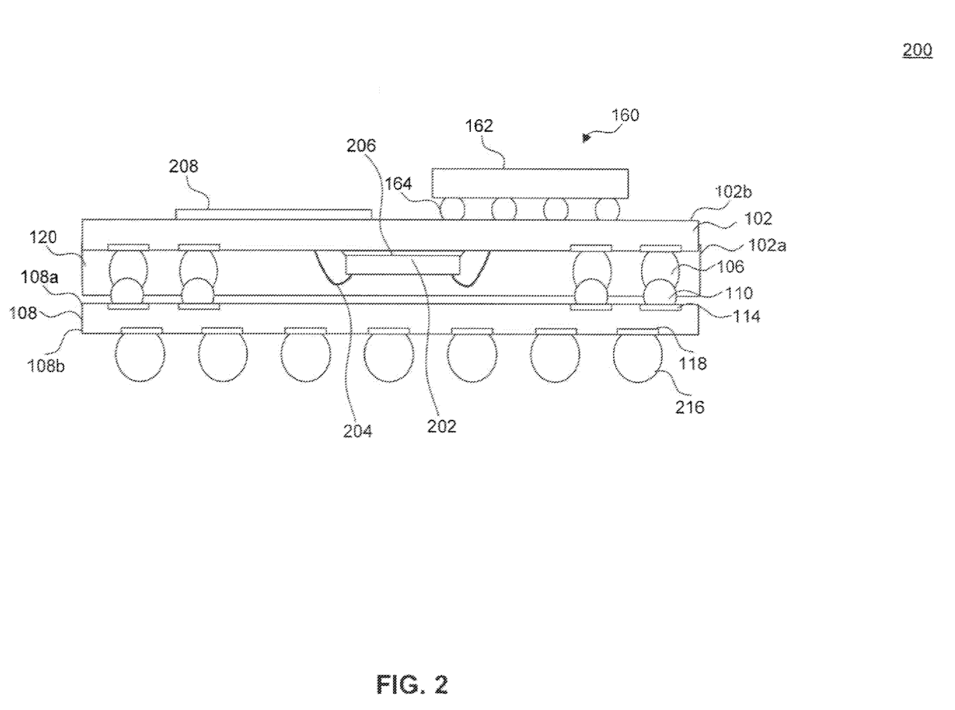

FIG. 2 shows a cross-sectional diagram of an IC package 200, according to an embodiment. IC package 200 is substantially similar to IC package 100 shown in FIG. 1, except that IC die 104 is replaced with an IC die 202. As shown in FIG. 2, IC die 202 is coupled to first surface 102a of substrate 102 in a die up configuration. Wire bonds 204 couple conductive regions on IC die 202 (not shown) to conductive regions on substrate 102. Moreover, in some situations adhesive 206 can be used to attach IC die 202 to first surface 102a of substrate 102.

Moreover, as shown in FIG. 2, IC package 200 also includes an antenna 208. Antenna 208 can be implemented using traces formed on second surface 102b of substrate 102. For example, antenna 208 can be implemented as a dipole antenna. In an embodiment, antenna 208 can be electrically coupled to IC die 202 through substrate 102. In such an embodiment, IC die 202 can use antenna 208 to communicate with other devices, e.g., other devices mounted on a PCB.

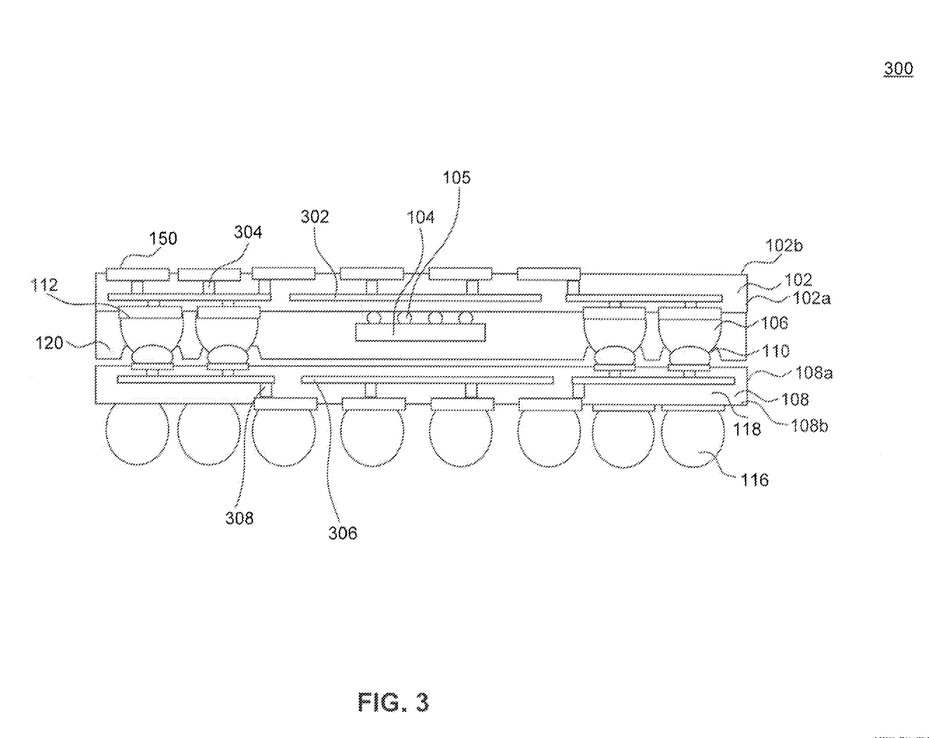

FIG. 3 shows a cross-sectional diagram of an IC package 300, according to an embodiment. IC package 300 is substantially similar to IC packages 100 and 200, described with reference to FIGS. 1 and 2, except that packages 140 and 160 have been removed from second surface 102b of substrate 102. Moreover, FIG. 3 also shows a view that highlights the internal structure of substrate 102 and interposer 108. For example, as shown in FIG. 3, substrate 102 can include one or more patterned metal layers 302. Patterned metal layer 302 can be electrically coupled to conductive regions 112 and 150 through vias 304. Although not shown in FIG. 3, traces can be formed on second surface 102b and/or first surface 102a of substrate 102 and can also be used to electrically couple to different portions of substrate 102. Moreover, traces can also be formed within substrate 102 (e.g., using one or more embedded metal layers).

Moreover, as shown in FIG. 3, interposer 108 includes one or more patterned metal layers 306 that are coupled to respective conductive regions 118 through vias 308. Similar to substrate 102, interposer 108 can include traces on first surface 108a and/or second surface 102b that electrically couple different portions of the respective surface. Furthermore, traces can also be formed within interposer 108 (e.g., using one or more embedded metal layers).

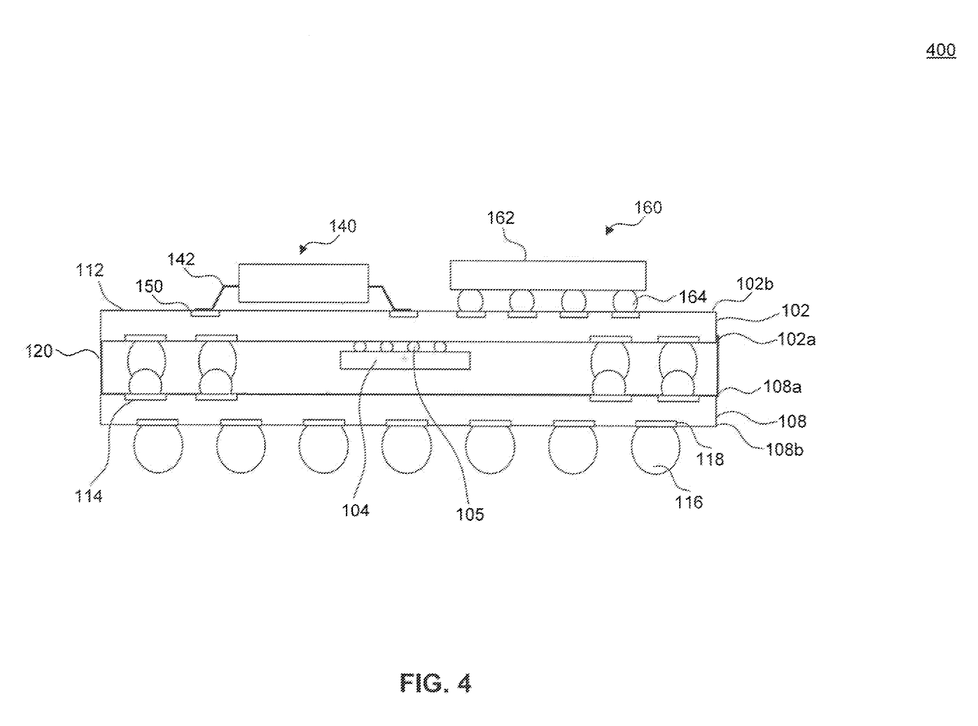

FIG. 4 shows a cross-sectional diagram of an IC package 400, according to an embodiment. IC package 400 is substantially similar to IC package 100, described with reference to FIG. 1, except that there is no gap between the outer surface of encapsulation material 120 and first surface 108a of interposer 108.

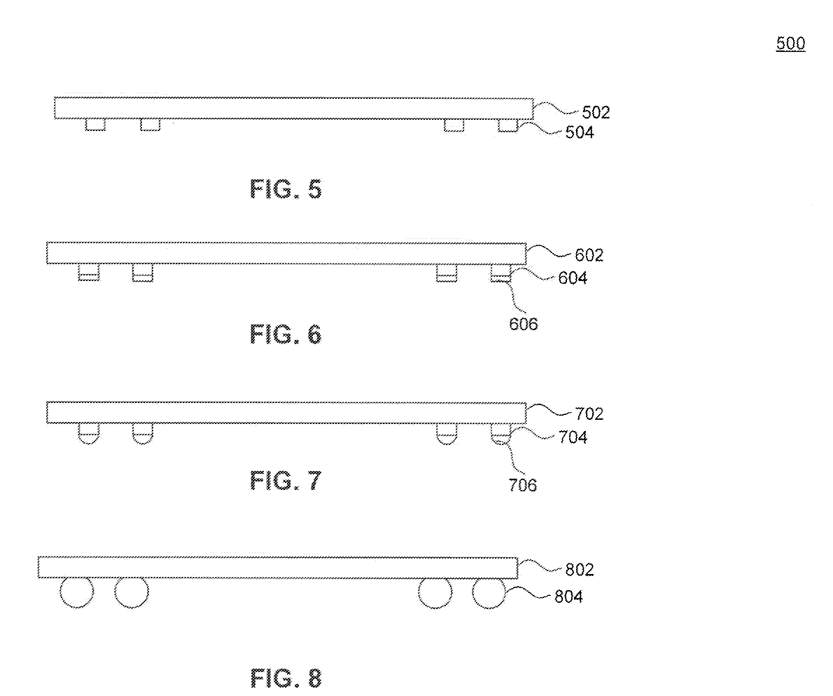

FIGS. 5-8 show different embodiments of a substrate. As would be appreciated by those skilled in the art based on the description herein, any of the substrates shown in FIGS. 5-8 can be used in the IC packages shown in FIGS. 1-4 and 9-13.

FIG. 5 shows a cross-sectional view of a substrate 502, according to an embodiment. As shown in FIG. 5, substrate 502 is coupled to conductive pillars 504. Conductive pillars 504 can be formed out of a variety of different electrically conductive materials. e.g., copper or aluminum.

FIG. 6 shows a cross-sectional diagram of a substrate 602, according to an embodiment. As shown in FIG. 6, posts 604 are coupled to interposer 602. Posts 604 can also be formed out of an electrically conductive material, e.g., copper or aluminum. Moreover, as shown in FIG. 6, each of posts 604 can be plated with a plating material 606. The plating material can include an electrically conductive material to facilitate electrical coupling, e.g., solder, tin, or an alloy.

FIG. 7 shows a cross-sectional diagram of a substrate 702. As shown in FIG. 7, interposer 702 is coupled to posts 702. Each of posts 704 is coupled to a respective cap 706. Caps 706 can include an electrically conductive material that facilitates electrical coupling, e.g., solder, tin, or an alloy. Caps 706 can be configured to enhance the coupling between posts 704 and another plurality of conductive elements, e.g., a plurality of solder balls.

FIG. 8 shows a cross-sectional diagram of a substrate 802 according to an embodiment. As shown in FIG. 8, substrate 802 is coupled to solder balls 804. Solder balls 804 can be used to establish an electrical conductivity with an interposer, e.g., through another plurality of conductive elements coupled to the interposer.

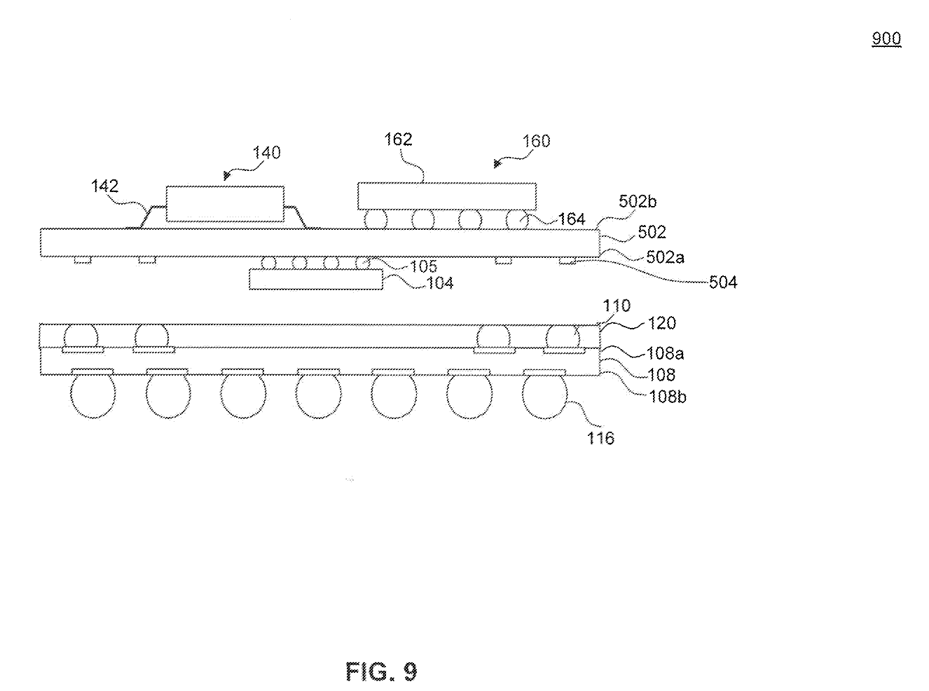

FIG. 9 shows a cross-sectional, exploded view diagram of an IC package 900, according to an embodiment. IC package 900 is substantially similar to IC package 100, described with reference to FIG. 1 except that substrate 102 is replaced with substrate 502 (shown in FIG. 5) and each of second plurality of conductive elements 110 is exposed out at the surface of encapsulation material 120. In an embodiment, exposing first plurality of conductive elements at the outer surface of encapsulation material 120 can facilitate electrical connection between pillars 504 and second plurality of conductive elements 110.

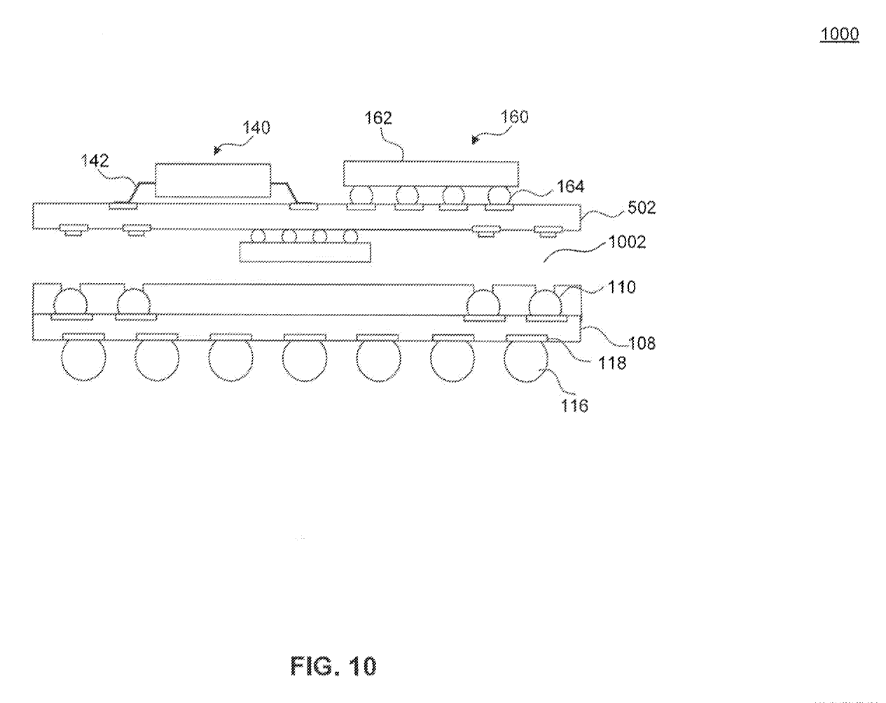

FIG. 10 shows as cross-sectional diagram of an IC package 1000 according to an embodiment. IC package 1000 is substantially similar to IC package 900, described with reference to FIG. 9, except that each of conductive elements 110 is exposed at the outer surface of encapsulation material 120 through openings 1002 formed an encapsulation material 120. In an embodiment, openings 1002 can be formed by drilling holes into encapsulation material 120.

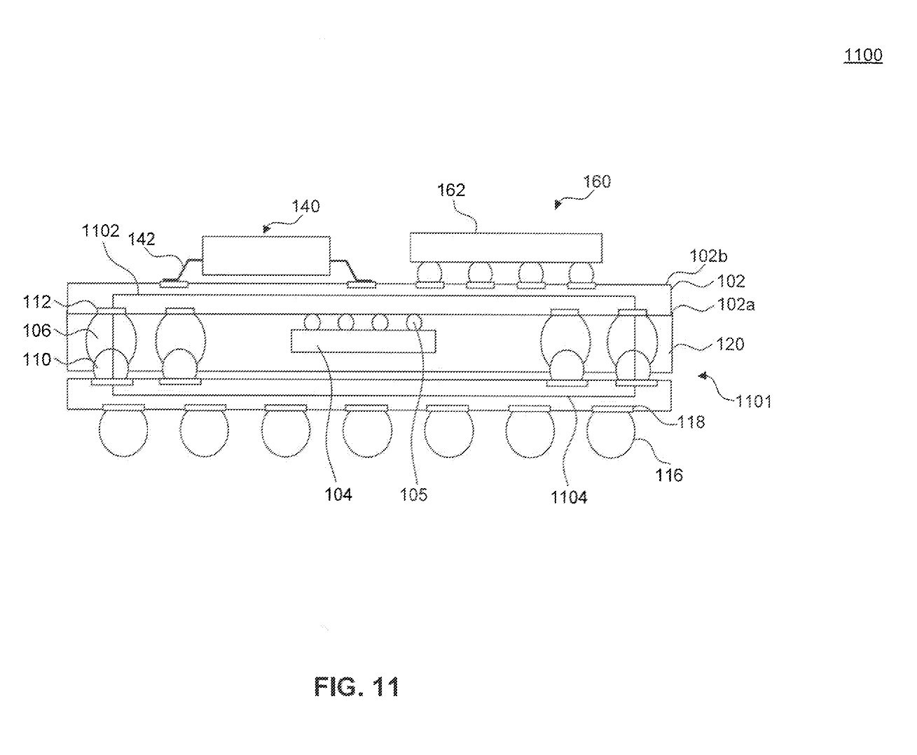

FIG. 11 shows a cross-sectional diagram of an IC package 1100, according to an embodiment. IC package 1100 is substantially similar to IC package 100, described with reference to FIG. 1, except that IC package 1100 includes a Faraday cage 1101. For example, as shown in FIG. 11, Faraday cage 1101 includes metal layers 1102 and 1104 of substrate 102 and interposer 108, respectively. Metal layers 1102 and 1104 can be electrically coupled through two or more pairs of first and second pluralities of conductive elements 106 and 110 to form a loop around IC die 104.

Moreover, to form a Faraday cage, this loop can be coupled to a ground potential. Faraday cage 1101 can prevent electromagnetic interference from affecting die 104. Faraday cage 1101 can also prevent radiation produced by IC die 104 from escaping package 1100 and affecting other devices.

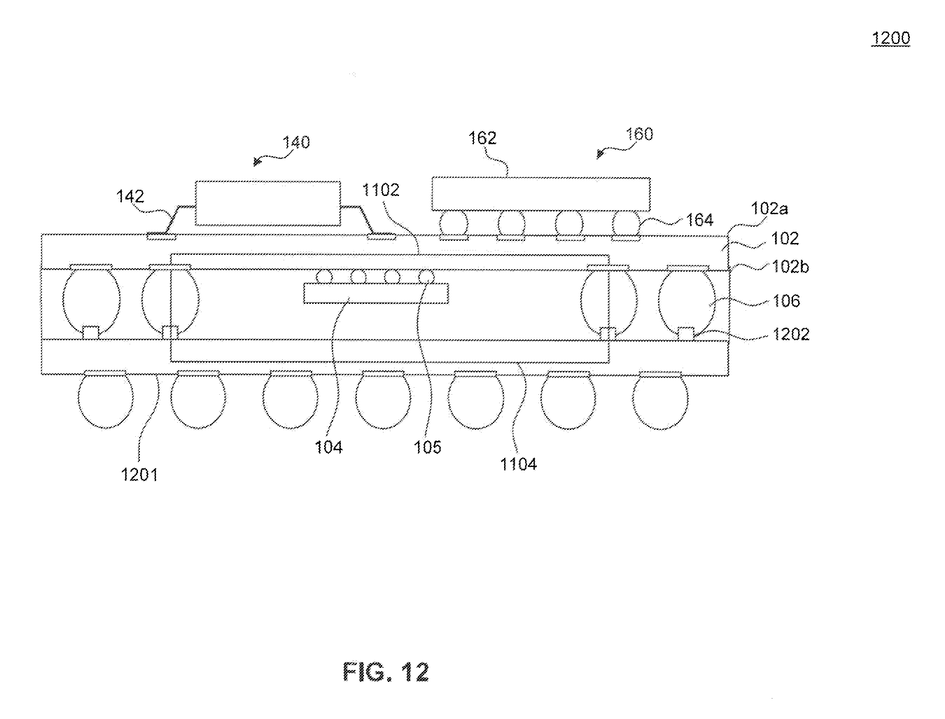

FIG. 12 shows a cross-sectional diagram of an IC package 1200, according to an embodiment. IC package 1200 is substantially similar to IC package 1100, except that Faraday cage 1101 is replaced with to Faraday cage 1201. In particular, instead of forming the Faraday cage using outer ones of the first and second pluralities of conductive elements 106 and 110. Faraday cage 1201 is formed using inner ones of the first and second pluralities of conductive elements 106 and 110. Moreover, as shown in FIG. 12, second plurality of conductive elements 110 are replaced with conductive posts 1202.

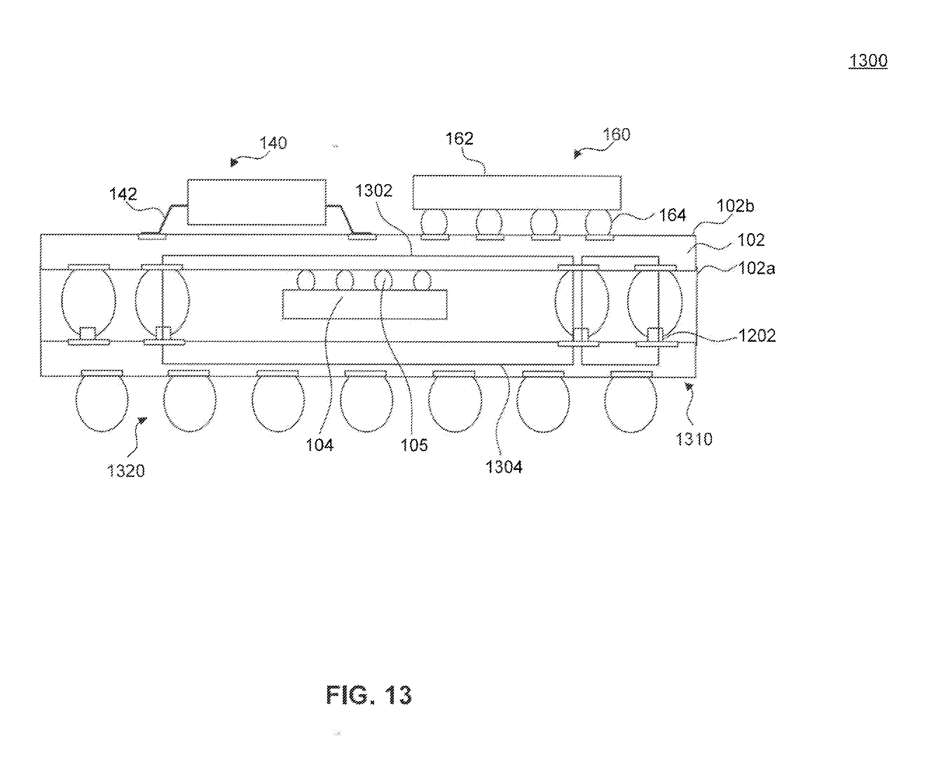

FIG. 13 shows a cross-sectional diagram of an IC package 1300, according to an embodiment. IC package 1300 is substantially similar to IC package 1200, described with reference to FIG. 12, except that IC package 1300 includes two Faraday cages: a first Faraday cage 1310 and a second Faraday cage 1320. In particular, as shown in FIG. 13, metal layers 1302 and 1304 of substrate 102 and interposer 108, respectively, can be patterned such that two separate loops can be formed within IC package 1300. The use of two loops included in the same package can provide isolation for specific components as well as for IC die 104.

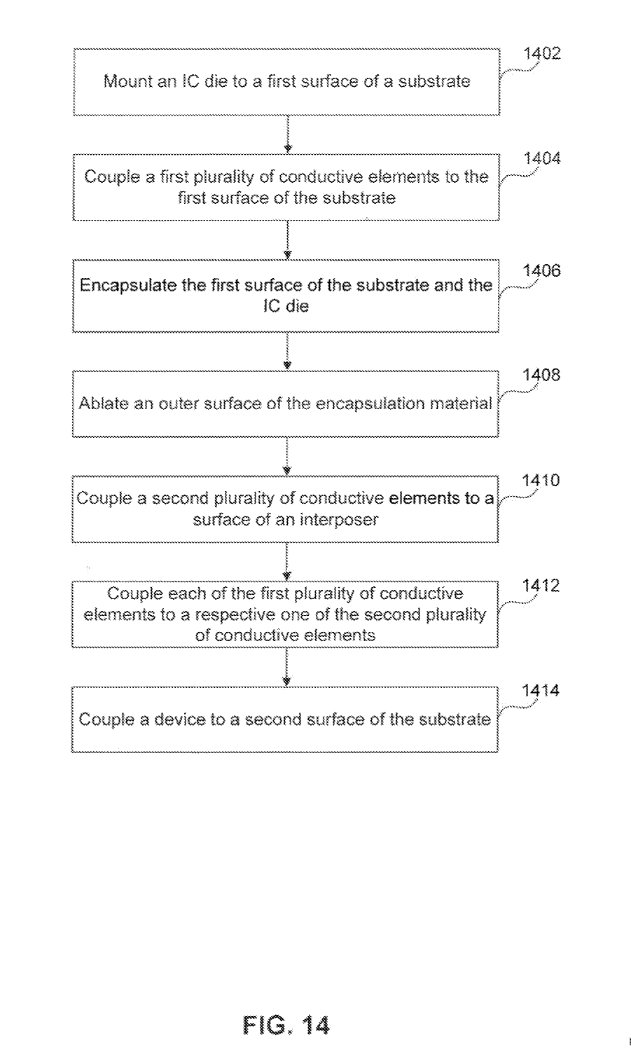

FIG. 14 shows a method of manufacturing and IC device 1400, according to an embodiment. Not all steps of method 1400 may be required, nor do all of these steps shown in FIG. 14 necessarily have to occur in the order shown.

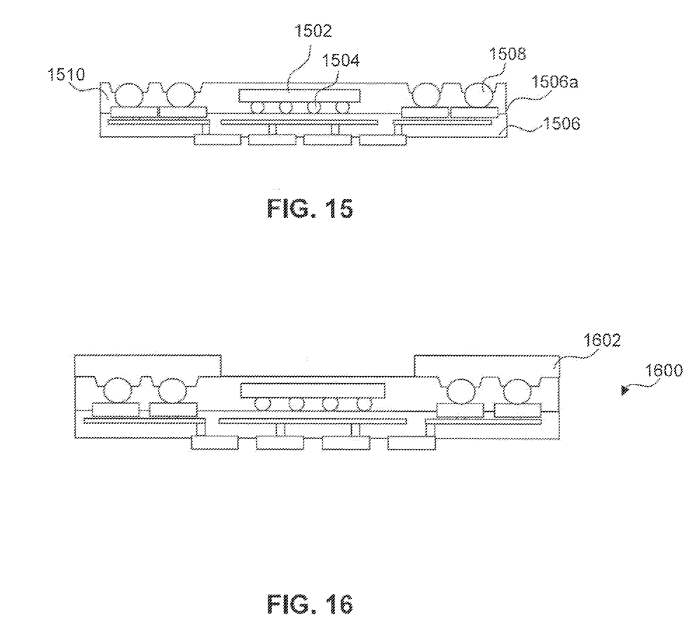

In step 1402, an IC die is mounted to a first surface of substrate. For example, in FIG. 15, IC die 1502 is mounted to a first surface 1506a of substrate 1506. As shown in FIG. 15, IC die 1502 is coupled to substrate 1506 through solder bumps 1504.

In step 1404, a first plurality of conductive elements is coupled to the first surface of the substrate. For example, in FIG. 15, a first plurality of conductive elements 1508 is coupled to first surface 1506a of substrate 1506. In an embodiment, both IC die 1502 and first plurality of conductive elements 1508 can be coupled to surface 1506a of substrate 1506 in a reflow process.

In step 1406, the first surface of the substrate in the IC die is encapsulated. For example, in FIG. 15, the first surface 1506a and IC die 1502 can be encapsulated in an encapsulation material 1510.

In step 1408, an outer surface of the encapsulation material is ablated. For example, in FIG. 15, an outer surface of encapsulation material 1510 can be ablated to expose at least a portion of each one of first plurality of conductive elements 1508. In a further embodiment, after ablation, flux can be dispensed on expose portions of first plurality of conductive elements 1508. For example, as shown in FIG. 16, flux material 1602 can be dispensed on outer surface of encapsulation material 1510 and expose portions of first plurality of conductive elements 1508 resulting in device 1600. In an embodiment, the flux material can enhance connectivity between the first and second pluralities of conductive elements. Step 1408 can be optional. For example, connections to first plurality of conductive elements 1508 can be instead be facilitated by drilling holes in encapsulation material 1510.

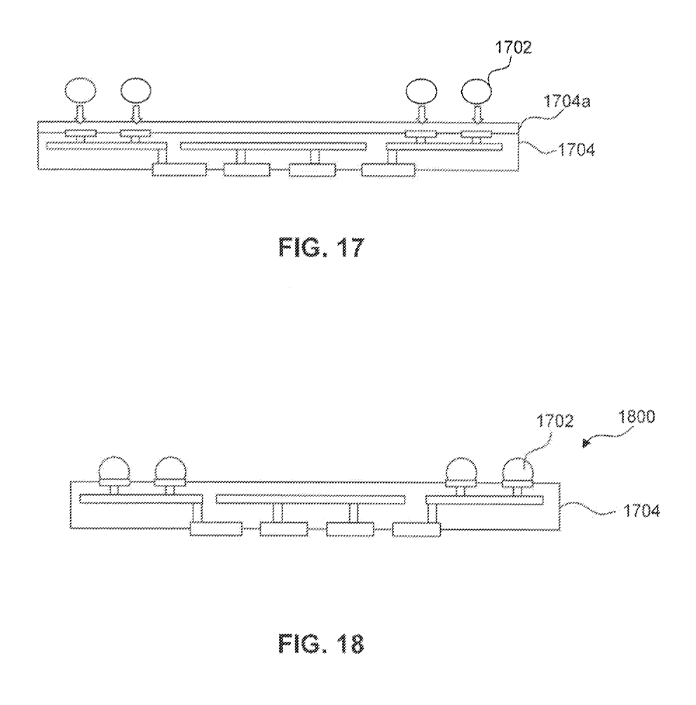

In step 1410, a second plurality of conductive elements is coupled to a surface of an interposer. For example, in FIG. 17, second plurality of conductive elements 1702 is coupled to respective portions of first surface 1704a of substrate 1704 to produce device 1800.

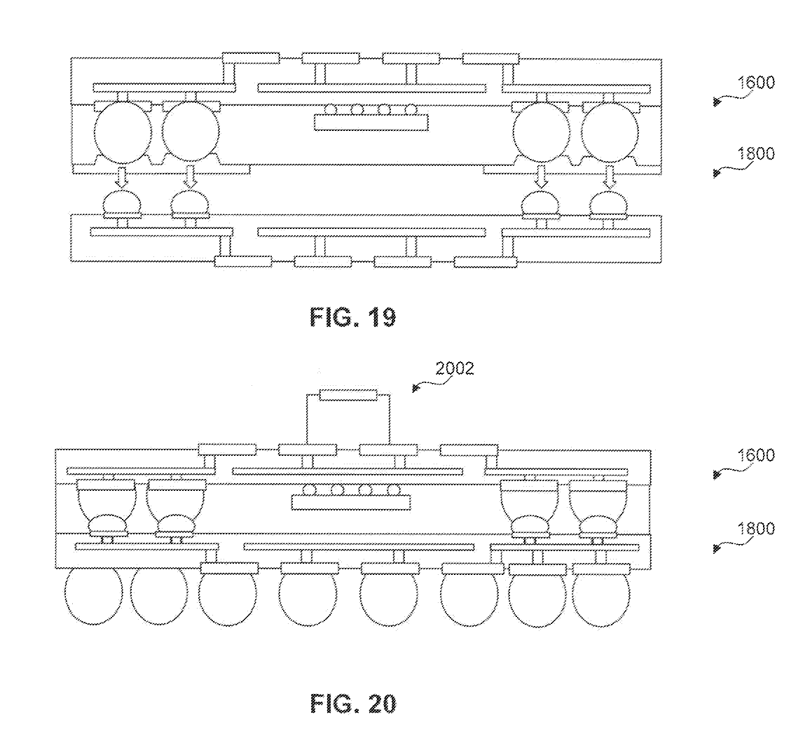

In step 1412, each of the first plurality of conductive elements is coupled to a respective one of the second plurality of conductive elements. For example, as shown in FIG. 19, device 1600 can be placed on device 1800 causing a mechanic contact between first and second pluralities of conductive elements 1508 and 1704. Thereafter, a reflow process can be used to join first and second pluralities of conductive elements 1508 and 1704.

In step 1414, a device is coupled to a second surface of the substrate. The second device can be, e.g., a package including an IC die, an antenna, or a passible component (e.g., a capacitor, resistor, inductor, or balun). For example, as shown in FIG. 20, an electric device 2002 is coupled to top surface 1608a of substrate 1600. In an embodiment, device 2002 can be electrically coupled to the IC die through substrate 1600.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. An integrated circuit (IC) package, comprising:
a substrate having opposing first and second surfaces;
an IC die coupled to the first surface of the substrate, wherein the second surface of the substrate is configured be coupled to at least one device;
a first plurality of conductive elements coupled to conductive regions on the first surface of the substrate;
an interposer having opposing first and second surfaces; and
a second plurality of conductive elements coupled to conductive regions on the first surface of the interposer, wherein each of the first plurality of conductive elements is electrically coupled to a respective one of the second plurality of conductive elements.

2. The IC package of claim 1, farther comprising:
a device coupled to the second surface of the substrate, wherein the device is electrically coupled to the IC die through the substrate.

3. The IC package of claim 2, wherein the device comprises a second IC die.

4. The IC package of claim 3, wherein the second IC die comprises a memory.

5. The IC package of claim 4, wherein the IC die comprises a processor and wherein the processor is configured to store data in the memory.

6. The IC package of claim 2, wherein the device comprises an antenna.

7. The IC package of claim 1, further comprising an encapsulation material that encapsulates the first surface of the substrate and the IC die.

8. The IC package of claim 7, wherein a gap is present between an outer surface of the encapsulation material and the first surface of the interposer.

9. The IC package of claim 1, wherein the first plurality of conductive elements comprises a solder ball.

10. The IC package of claim 1, wherein the second plurality of conductive elements comprises a solder ball.

11. The IC package of claim 1, wherein the second plurality of conductive elements comprises a post.

12. The IC package of claim 11, wherein a solder cap is coupled to the post.

13. The IC package of claim 1, further comprising a third plurality of conductive elements coupled to the second surface of the interposer.

14. The IC package of claim 13, wherein the IC die is electrically coupled to the third plurality of conductive elements through the substrate.

15. The IC package of claim 1, wherein the substrate, the interposer, at least two of the first plurality of conductive elements, and at least two of the second plurality of conductive elements are configured to form a Faraday cage.

16. The IC package of claim 15, wherein the Faraday cage is configured to surround the IC die.

17-20. (canceled)

21. An integrated circuit (IC) package configured to be mounted to a printed circuit board (PCB), comprising:
a substrate having opposing first and second surfaces:
an IC die coupled to the first surface of the substrate, wherein the second surface of the substrate is configured be coupled to at least one device; and
a plurality of conductive elements coupled to conductive regions on the first surface of the substrate;
wherein the IC die is configured to be electrically coupled to the PCB through the plurality of conducive elements.

22. The IC package of claim 21, further comprising:
a device coupled to the second surface of the substrate, wherein the device is electrically coupled to the IC die through the substrate.

23. The IC package of claim 22, wherein the device comprises a second IC die.

24. The IC package of claim 22, wherein the device comprises all antenna.
